(19) United States
(12) Patent Application Publication
(10) Pub. No.: US 2026/0236345 A1
(43) Pub. Date: Aug. 13, 2026

(54) MEMORY DEVICE

(71) Applicant: Winbond Electronics Corp., Taichung City (TW)

(72) Inventor: Yong Ju Kim, Zhubei City (TW)

(73) Assignee: Winbond Electronics Corp., Taichung City (TW)

(21) Appl. No.: 19/050,059

(22) Filed: Feb. 10, 2025

(51) Int. Cl. G06F 11/10; H01L 25/065; H01L 25/18; H10B 80/00

(52) U.S. Cl. CPC G06F 11/1044; H10B 80/00; H10W 90/00; H10W 90/297

(57) ABSTRACT

The memory device is provided. The memory device includes at least one core die and a logic die. The at least one core die provides at least two state signals based on error check and correction (ECC) operation. The logic die is coupled to the least one core die. The logic die generates the at least two state signals to generate a plurality of severity (SEV) signals. A number of the at least two state signals is lower than a number of the plurality of SEV signals.

### BACKGROUND

### Technical Field

The disclosure generally relates to a memory device, and more particularly to a memory device providing severity signals.

### Description of Related Art

FIG. 1 illustrates a schematic diagram of a memory device. Generally, the memory device includes core dies CD1 to CD8 and a logic die LD. Each of the core dies CD1 to CD8 can provide a severity (SEV) signal SEV[0] having 8 bits and a SEV signal SEV[1] having 8 bits based on error check and correction (ECC) operation. The logic die outputs a serial severity signal SSEV[0] and a serial severity signal SSEV[1] to a controller CC.

It should be noted, each of the 8 core dies CD1 to CD8 needs up to 16 channels to transmit the SEV signals SEV[0] and SEV[1]. Each of the channels has “2” pseudo-channels. Each of the pseudo-channels has 2 pins or 2 die-to-die (D2D) interconnecting structures. Each of the core dies CD1 to CD8 needs up to 64 (that is, 16×2×2) pins or interconnecting structures. Therefore, the core dies CD1 to CD8 need up to 512 (that is, 16×2×2×8) pins or interconnecting structures. In other words, the memory device needs 512 via (for example, TSV) structures for transmitting the SEV signals SEV[0] and SEV[1]. The increase of a number of via structures for transmitting the SEV signals SEV[0] and SEV[1] would increase design complexity of the memory device.

Therefore, how to decrease the number of via structures is one of the research and development focuses of those skilled in the art.

### SUMMARY

The disclosure provides a memory device. A number of via structures of at least one core die of the memory device can be decreased.

In an embodiment of the disclosure, the memory device includes at least one core die and a logic die. The at least one core die provides at least two state signals based on error check and correction (ECC) operation. The logic die is coupled to the least one core die. The logic die generates the at least two state signals to generate a plurality of severity (SEV) signals. A number of the at least two state signals is lower than a number of the plurality of SEV signals.

Based on the above, the core die provides the at least two state signals based on ECC operation. The logic die generates the plurality of SEV signals according to the at least two state signals. The number of the at least two state signals is less than the number of the plurality of SEV signals. Therefore, a number of via structures of the at least one core die can be decreased. In this way, design complexity of the memory device can be decreased.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 illustrates a schematic diagram of a memory device.

FIG. 2, FIG. 3, FIG. 4, FIG. 7 and FIG. 8 illustrate a schematic diagram of a memory device according to some embodiments of the disclosure.

FIG. 5 and FIG. 9 illustrate a schematic diagram of a pre-encoder according to some embodiments of the disclosure.

FIG. 6 illustrates a schematic diagram of a severity (SEV) signal generator according to an embodiment of the disclosure.

### DESCRIPTION OF THE EMBODIMENTS

A disclosure may be understood by reference to the following detailed description, taken in conjunction with the drawings as described below. It is noted that, for purposes of illustrative clarity and being easily understood by the readers, various drawings of this disclosure show a portion of an electronic device, and certain elements in various drawings may not be drawn to scale. In addition, the number and dimension of each device shown in drawings are only illustrative and are not intended to limit the scope of a disclosure.

It will be understood that when an element is referred to as being “coupled to”, “connected to”, or “conducted to” another element, it may be directly connected to the other element and established directly electrical connection, or intervening elements may be presented therebetween for relaying electrical connection (indirectly electrical connection). In contrast, when an element is referred to as being “directly coupled to”, “directly conducted to”, or “directly connected to” another element, there are no intervening elements presented.

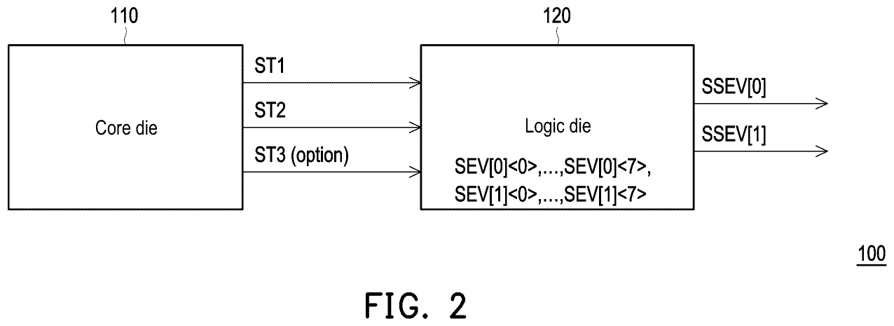

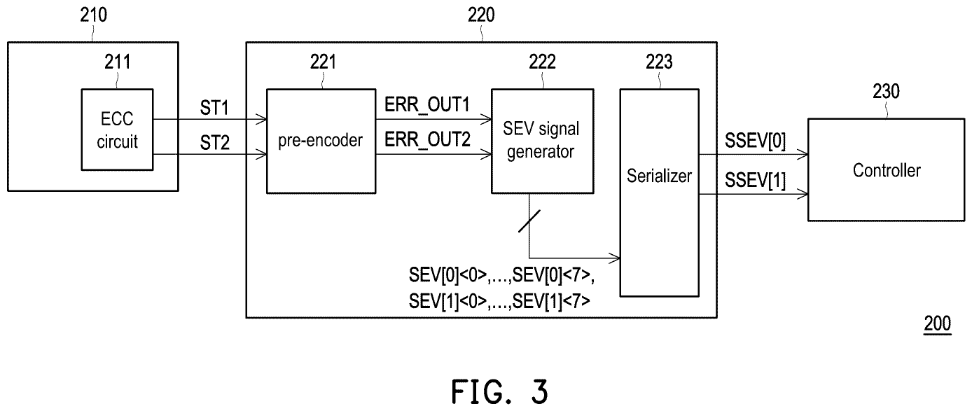

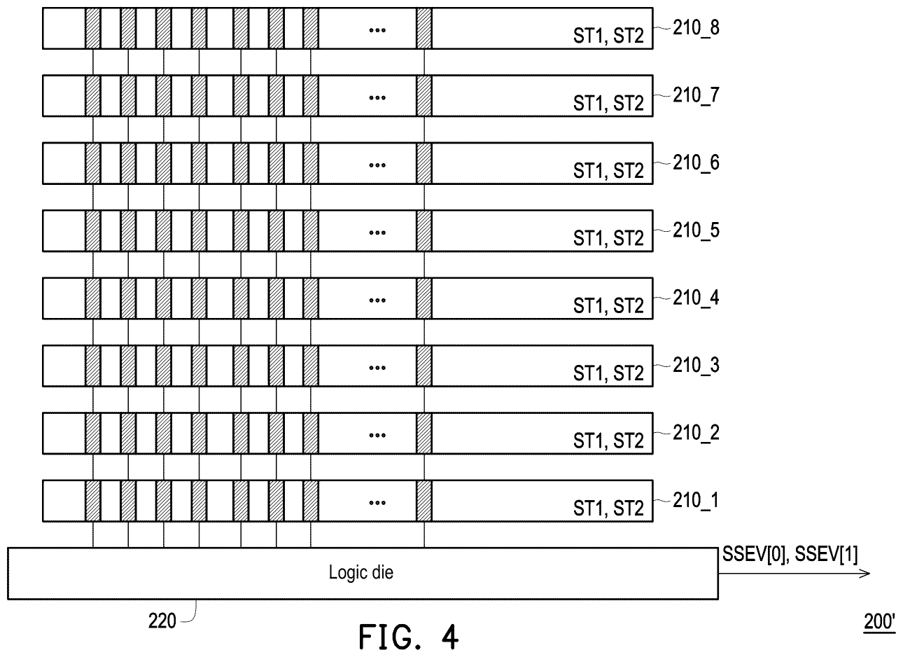

Please refer to FIG. 2, FIG. 2 illustrates a schematic diagram of a memory device according to an embodiment of the disclosure. In the embodiment, the memory device 100 includes a core die 110 and a logic die 120. The core die 110 provides state signals based on error check and correction (ECC) operation. The state signals correspond to a result of ECC operation of the core die 110. For example, the core die 110 provides two state signals ST1 and ST2 based on the ECC operation. For example, the core die 110 provides three state signals ST1, ST2 and ST3 based on the ECC operation.

In the embodiment, the logic die 120 generates the state signals to generate severity (SEV) signals SEV[0]<0> to SEV[0]<7> and SEV[1]<0> to SEV[1]<7>. A number of the at least two state signals is less than a number of the SEV signals SEV[0]<0> to SEV[0]<7> and SEV[1]<0> to SEV[1]<7>. For example, the number of the at least two state signals is “2” or “3”. A number of the SEV signals SEV[0]<0> to SEV[0]<7> and SEV[1]<0> to SEV[1]<7> is “16”.

It should be noted, the core die 100 provides the at least two state signals based on ECC operation. The logic die generates the plurality of SEV signals SEV[0]<0> to SEV[0]<7> and SEV[1]<0> to SEV[1]<7> according to the at least two state signals. The number state signals is less than the number of the plurality of SEV signals. Therefore, a number of via (for example, TSV) structures of the core die 100 is allowed to be decreased. In this way, design complexity of the memory device 100 can be decreased.

Furthermore, the logic die 120 generates at least one serial severity signal SSEV[0] and SSEV[1] according to the SEV signals SEV[0]<0> to SEV[0]<7> and SEV[1]<0> to SEV[1]<7>.

Please refer to FIG. 3, FIG. 3 illustrates a schematic diagram of a memory device according to an embodiment of the disclosure. In the embodiment, the memory device 200 includes a core die 210 and a logic die 220. The core die 210 provides the state signals ST1 and ST2 based on the ECC operation. The logic die 220 includes a pre-encoder 221 and a SEV signal generator 222. The pre-encoder 221 is coupled to the core die 210. The pre-encoder 221 generates a first error output signal ERR_OUT1 and a second error output signal ERR_OUT2 according to the state signals ST1 and ST2. The SEV signal generator 222 is coupled to the pre-encoder 221. The SEV signal generator 222 generates the SEV signals SEV[0]<0> to SEV[0]<7> and SEV[1]<0> to SEV[1]<7> according to the first error output signal ERR_OUT1 and the second error output signal ERR_OUT2.

It should be noted, based on the ECC operation, the core die 210 provides the state signals ST1 and ST2, but does not provide the SEV signals SEV[0]<0> to SEV[0]<7> and SEV[1]<0> to SEV[1]<7>. For example, each of 2 channels for transmitting the state signals ST1 and ST2 has 2 pseudo-channels. Each of the pseudo-channels has 2 pins or 2 die-to-die (D2D) interconnecting structures. Therefore, the core die 210 has up to 8 (that is, 2×2×2) pins or interconnecting structures. In other words, the core die 210 has 8 via structures for transmitting the state signals ST1 and ST2.

Besides, the logic die 220 further includes a serializer 223. The serializer 223 is coupled to the SEV signal generator 222. The serializer 223 generates at least one serial severity signal according to the SEV signals SEV[0]<0> to SEV[0]<7> and SEV[1]<0> to SEV[1]<7>. In the embodiment, the serializer 223 generates serial severity signal SSEV[0] according to the SEV signals SEV[0]<0> to SEV[0]<7> and generates serial severity signal SSEV[1] according to the SEV signals SEV[1]<0> to SEV[1]<7>. The serializer 223 may receive the SEV signals SEV[0]<0> to SEV[0]<7> and SEV[1]<0> to SEV[1]<7> parallelly, and generates the serial severity signals SSEV[0] and SSEV[1]. For example, the serializer 223 may be a parallel-to-serial converter.

In the embodiment, the memory device 200 further includes a controller 230. The controller 230 is coupled to the serializer 223. The controller 230 obtains an error type of the core die 210 according to the serial severity signal SSEV[0] and SSEV[1].

In the embodiment, the core die 210 includes an ECC circuit 211. The ECC circuit 211 performs the ECC operation of the core die 210 to generate the state signals ST1 and ST2. The ECC operation of the disclosure is not limited.

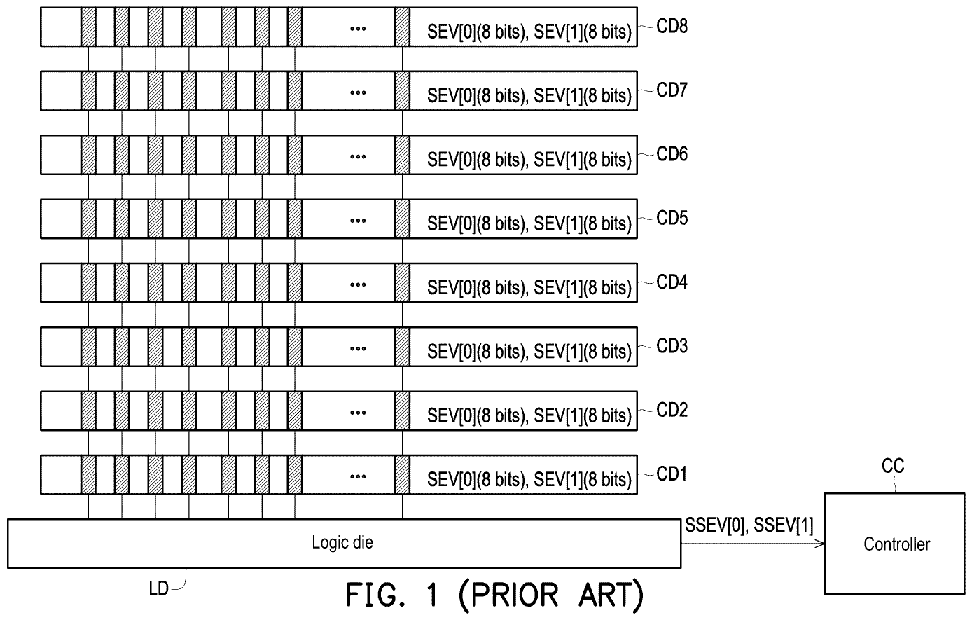

Please refer to FIG. 3 and FIG. 4, FIG. 4 illustrates a schematic diagram of a memory device according to an embodiment of the disclosure. In the embodiment, the memory device 200′ includes core dies 210_1 to 210_8 and a logic die 220. The core dies 210_1 to 210_8 are stacked on each other. Each of the core dies 210_1 to 210_8 can be implemented by the core die 210. Each of the core dies 210_1 to 210_8 has 8 via structures for transmitting the state signals ST1 and ST2. Thus, comparing the memory device in the FIG. 1, a total number of via structures of the core dies 210_1 to 210_8 of the memory device 200′ can be decreased from “512” to “64”.

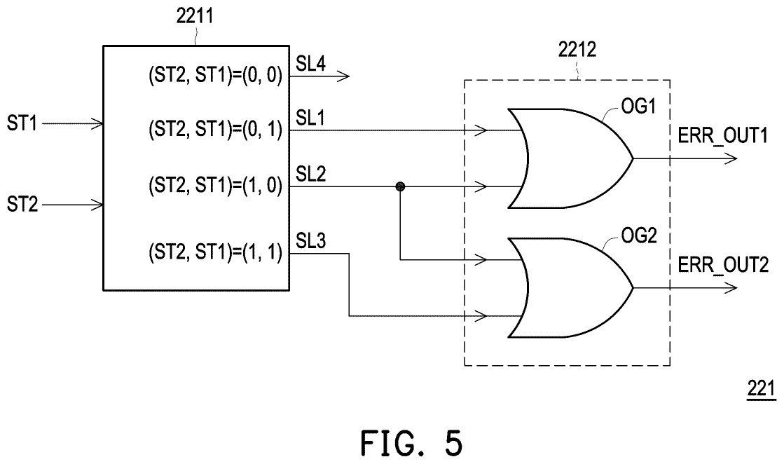

Please refer to FIG. 5, FIG. 5 illustrates a schematic diagram of a pre-encoder according to an embodiment of the disclosure. In the embodiment, the pre-encoder 221 includes a decoder 2211 and a logic circuit 2212. The decoder 2211 generates logic signals SL1 to SL3 in response to logic values of the first state signal ST1 and the second state signal ST2. The logic circuit 2212 is coupled to the decoder 2211. The logic circuit 2212 generates the first error output signal ERR_OUT1 and the second error output signal ERR_OUT2 according to the logic signals SL1 to SL3.

The logic signals SL1 corresponds to a correct error single bit (CEs) state. The logic signal SL2 corresponds to a correct error multibit (CEm) state. The logic signal SL3 corresponds to an uncorrectable error bit (UE) state.

In the embodiment, the pre-encoder 221 generates the first error output signal ERR_OUT1 and the second error output signal ERR_OUT2 based on Table 1.

TABLE 1

| | ERR_OUT1 | ERR_OUT2 | ST1 | ST2 |
|---|---|---|---|---|
| NE | 0 | 0 | 0 | 0 |
| CEs | 1 | 0 | 1 | 0 |
| CEm | 1 | 1 | 0 | 1 |
| UE | 0 | 1 | 1 | 1 |

Based on Table 1, when a logic value of the state signals ST1 is a first logic value (for example, low logic value “0”) and a logic value of the state signals ST2 is the first logic value, the decoder 2211 generates a logic signals SL4 having a second logic value (for example, high logic value “1”) corresponding to a no error (NE) state. Each of logic values of the logic signals SL1 to SL3 is the first logic value. When a logic value of the state signals ST1 is the second logic value and a logic value of the state signals ST2 is the first logic value, the decoder 2211 generates the logic signals SL1 having the second logic value corresponding to the “CEs” state. Each of logic values of the logic signals SL2 to SL4 is the first logic value. When a logic value of the state signals ST1 is the first logic value and a logic value of the state signals ST3 is the second logic value, the decoder 2211 generates the logic signals SL3 having the second logic value corresponding to the “CEm” state. Each of logic values of the logic signals SL1, SL3 and SL4 is the first logic value. When a logic value of the state signals ST1 is the second logic value and a logic value of the state signals ST3 is the second logic value, the decoder 2211 generates the logic signals SL3 having the second logic value corresponding to the “UE” state. Each of logic values of the logic signals SL1, SL2 and SL4 is the first logic value.

In the embodiment, the decoder 2211 may be implemented by two-bits decoder.

The logic circuit 2212 performs first OR logic operation on the logic signals SL1 and SL2 to generate the first error output signal ERR_OUT1, and performs second OR logic operation on the logic signals SL2 and SL3 to generate the second error output signal ERR_OUT2.

In the embodiment, the logic circuit 2212 includes OR gates OG1 and OG2. A first input terminal of the OR gate OG1 receives the logic signal SL1. A second input terminal of the OR gate OG1 receives the logic signal SL2. An output terminal of the OR gate OG1 outputs the first error output signal ERR_OUT1. A first input terminal of the OR gate OG2 receives the logic signal SL2. A second input terminal of the OR gate OG2 receives the logic signal SL3. An output terminal of the OR gate OG2 outputs the second error output signal ERR_OUT2.

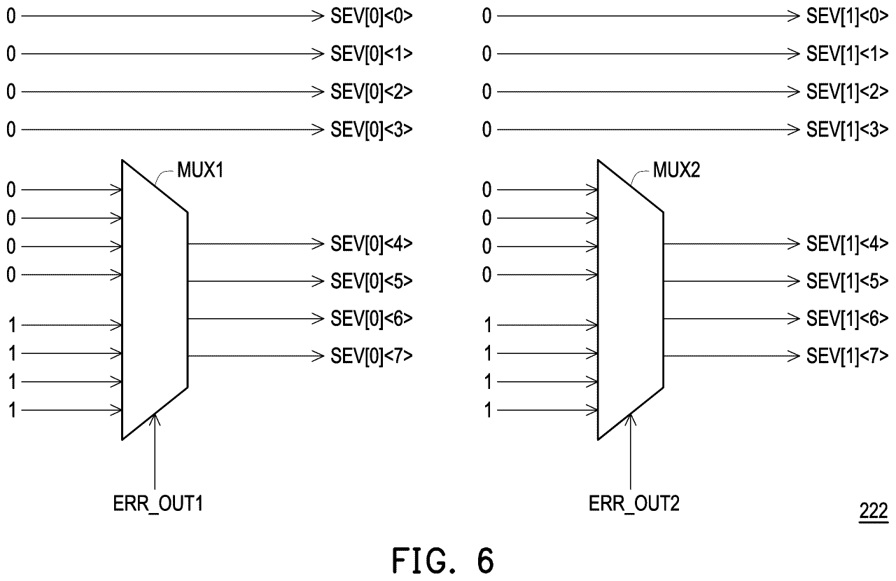

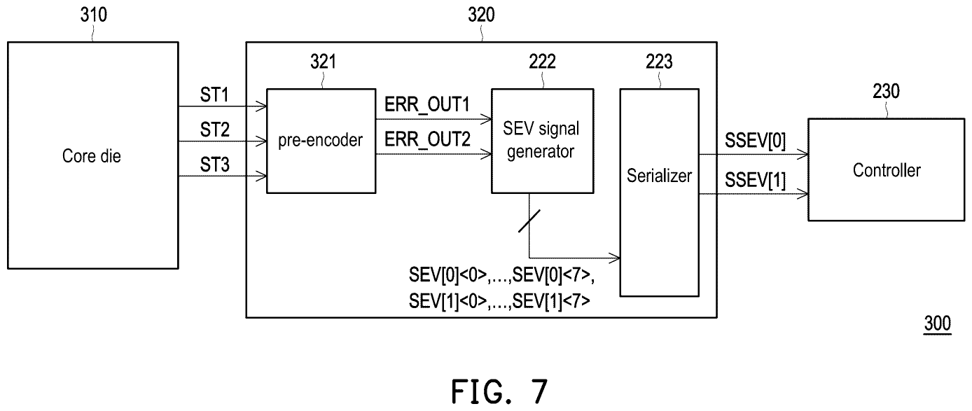

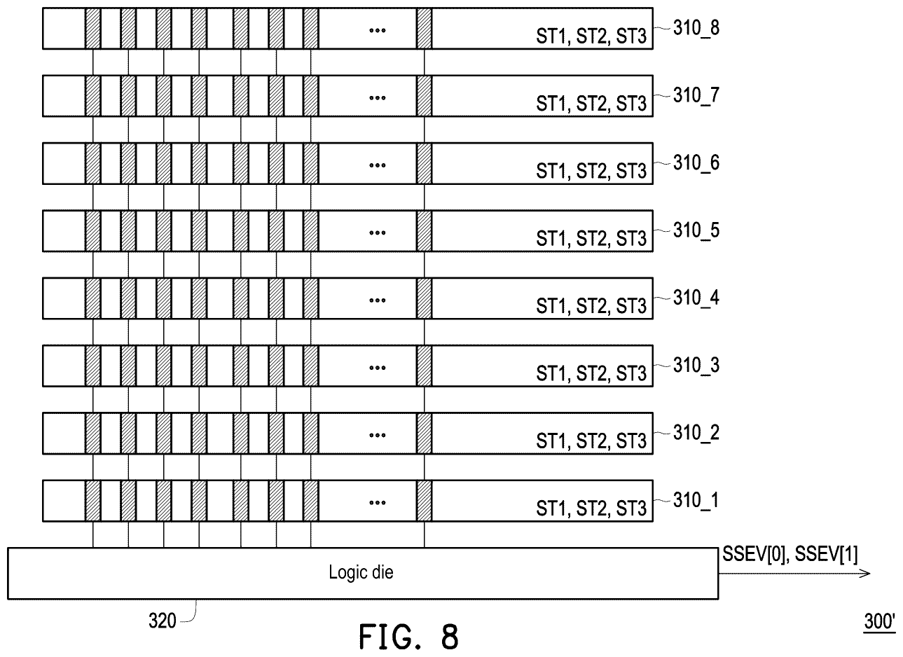

Please refer to FIG. 6, FIG. 6 illustrates a schematic diagram of a severity (SEV) signal generator according to an embodiment of the disclosure. In the embodiment, the SEV signals SEV[0]<0> to SEV[0]<7> are grouped into a first signal group including the SEV signals SEV[0]<0> to SEV[0]<3> and a second signal group including the SEV signals SEV[0]<4> to SEV[0]<7>. The SEV signals SEV[1]<0> to SEV[1]<7> are also grouped into a first signal group including the SEV signals SEV[1]<0> to SEV[1]<3> and a second signal group including the SEV signals SEV[1]<4> to SEV[1]<7>.

The SEV signal generator 222 provides the SEV signals SEV[0]<0> to SEV[0]<3> and SEV[1]<0> to SEV[1]<3> having the first logic value (for example, low logic value “0”). The SEV signal generator 222 provides the SEV signals SEV[0]<4> to SEV[0]<7> according to the first error output signal ERR_OUT1, and provides the SEV signals SEV[1]<4> to SEV[1]<7> according to the second error output signal ERR_OUT2. In other words, The SEV signal generator 222 provides the first signal group having the first logic value (for example, low logic value “0”) and provides the second signal group according to the first error output signal ERR_OUT1 and the second error output signal ERR_OUT2.

The SEV signal generator 222 includes multiplexers MUX1 and MUX2. The multiplexer MUX1 receives the first logic value, the second logic value (for example, high logic value “1”) and the first error output signal ERR_OUT1. When a logic value of the first error output signal ERR_OUT1 is the first logic value, the logic values of the SEV signals SEV[0]<0> to SEV[0]<7> are “0, 0, 0, 0, 0, 0, 0, 0” respectively. When a logic value of the first error output signal ERR_OUT1 is the second logic value, the logic values of the SEV signals SEV[0]<0> to SEV[0]<7> are “0, 0, 0, 0, 1, 1, 1, 1” respectively. The multiplexer MUX2 receives the first logic value, the second logic value (for example, high logic value “1”) and the second error output signal ERR_OUT2. When a logic value of the second error output signal ERR_OUT2 is the first logic value, the logic values of the SEV signals SEV[1]<0> to SEV[1]<7> are “0, 0, 0, 0, 0, 0, 0, 0” respectively. When a logic value of the second error output signal ERR_OUT2 is the second logic value, the logic values of the SEV signals SEV[0]<0> to SEV[0]<7> are “0, 0, 0, 0, 1, 1, 1, 1” respectively.

The SEV signal generator 222 provides the SEV signals SEV[0]<0> to SEV[0]<7> and SEV[1]<0> to SEV[1]<7> based on Table 2.

TABLE 2

| | | <0> | <1> | <2> | <3> | <4> | <5> | <6> | <7> |
|---|---|---|---|---|---|---|---|---|---|
| NE | SEV[0] | 0 | 0 | 0 | 0 | 0 | 0 | 0 | 0 |
| | SEV[1] | 0 | 0 | 0 | 0 | 0 | 0 | 0 | 0 |
| CEs | SEV[0] | 0 | 0 | 0 | 0 | 1 | 1 | 1 | 1 |
| | SEV[1] | 0 | 0 | 0 | 0 | 0 | 0 | 0 | 0 |
| CEm | SEV[0] | 0 | 0 | 0 | 0 | 1 | 1 | 1 | 1 |
| | SEV[1] | 0 | 0 | 0 | 0 | 1 | 1 | 1 | 1 |
| UE | SEV[0] | 0 | 0 | 0 | 0 | 0 | 0 | 0 | 0 |
| | SEV[1] | 0 | 0 | 0 | 0 | 1 | 1 | 1 | 1 |

Therefore, based on Table 1 and Table 2, when a logic value of the first error output signal ERR_OUT1 is a first logic value and a logic value of the second error output signal ERR_OUT2 is the first logic value, the SEV signals SEV[0]<0> to SEV[0]<7> and SEV[1]<0> to SEV[1]<7> indicate the “NE” state. When the logic value of the first error output signal ERR_OUT1 is a second logic value and the logic value of the second error output signal ERR_OUT2 is the first logic value, the plurality of severity signals SEV[0]<0> to SEV[0]<7> and SEV[1]<0> to SEV[1]<7> indicate the “CEs” state. When the logic value of the first error output signal ERR_OUT1 is the second logic value and the logic value of the second error output signal ERR_OUT2 is the second logic value, the plurality of severity signals SEV[0]<0> to SEV[0]<7> and SEV[1]<0> to SEV[1]<7> indicate the “CEm” state. When the logic value of the first error output signal ERR_OUT1 is the first logic value and the logic value of the second error output signal ERR_OUT2 is the second logic value, the plurality of severity signals SEV[0]<0> to SEV[0]<7> and SEV[1]<0> to SEV[1]<7> indicate the “UE” state.

Please refer to FIG. 7, FIG. 7 illustrates a schematic diagram of a memory device according to an embodiment of the disclosure. In the embodiment, the memory device 300 includes a core die 310 and a logic die 320. The core die 310 provides the state signals ST1, ST2 and ST3 based on the ECC operation. For example, the core die 310 provides the state signals ST1, ST2 and ST3 by an ECC circuit.

The logic die 320 includes a pre-encoder 321, the SEV signal generator 222 and the serializer 223. The pre-encoder 321 is coupled to the core die 310. The pre-encoder 321 generates the first error output signal ERR_OUT1 and the second error output signal ERR_OUT2 according to the state signals ST1, ST2 and ST3. The SEV signal generator 222 is coupled to the pre-encoder 321. The SEV signal generator 222 generates the SEV signals SEV[0]<0> to SEV[0]<7> and SEV[1]<0> to SEV[1]<7> according to the first error output signal ERR_OUT1 and the second error output signal ERR_OUT2.

It should be noted, based on the ECC operation, the core die 310 provides the state signals ST1, ST2 and ST3, but does not provide the SEV signals SEV[0]<0> to SEV[0]<7> and SEV[1]<0> to SEV[1]<7>. For example, each of “3” channels for transmitting the state signals ST1, ST2 and ST3 has 2 pseudo-channels. Each of the pseudo-channels has 2 pins or 2 die-to-die (D2D) interconnecting structures. Therefore, the core die 210 has up to 12 (that is, 3×2×2) pins or interconnecting structures. In other words, the core die 210 has 12 via structures for transmitting the state signals ST1, ST2 and ST3.

The memory device 300 further includes the controller 230. The operation of the SEV signal generator 222 has been clearly explained in the embodiments of FIG. 6, so it will not be repeated here. The controller 230 and the serializer 223 have been clearly explained in the embodiments of FIG. 3, so it will not be repeated here.

Please refer to FIG. 7 and FIG. 8, FIG. 8 illustrates a schematic diagram of a memory device according to an embodiment of the disclosure. In the embodiment, the memory device 300′ includes core dies 310_1 to 310_8 and a logic die 320. The core dies 310_1 to 310_8 are stacked on each other. Each of the core dies 310_1 to 310_8 can be implemented by the core die 310. Each of the core dies 310_1 to 310_8 has 12 via structures for transmitting the state signals ST1, ST2 and ST3. Thus, comparing the memory device in the FIG. 1, a number of via structures of the core dies 310_1 to 310_8 of the memory device 300′ can be decreased from “512” to “96”.

In the embodiment, the pre-encoder 321 generates the first error output signal ERR_OUT1 and the second error output signal ERR_OUT2 based on Table 3.

TABLE 3

| | ERR_OUT1 | ERR_OUT2 | ST1 | ST2 | ST3 |
|---|---|---|---|---|---|
| NE | 0 | 0 | 0 | 0 | 0 |
| CEs | 1 | 0 | 1(0) | 0(1) | 0 |
| CEm | 1 | 1 | 1 | 1 | 0 |
| UE | 0 | 1 | 1 | 1 | 1 |

In the embodiment, when a logic value of the state signal ST1 is the first logic value (for example, low logic value “0”), a logic value of the state signal ST2 is the first logic value and a logic value of the state signal ST3 is the first logic value, the pre-encoder 321 outputs the first error output signal ERR_OUT1 having the first logic value and the second error output signal ERR_OUT2 having the first logic value. When the logic value of the state signal ST1 is different from the logic value of the state signal ST2 and the logic value of the third state signal ST3 is the first logic value, the pre-encoder 321outputs the first error output signal ERR_OUT1 having the second logic value (for example, high logic value “1”) and the second error output signal ERR_OUT2 having the first logic value. When the logic value of the state signal ST1 is the second logic value, the logic value of the state signal ST2 is the second logic value and the logic value of the state signal ST3 is the first logic value, the pre-encoder 321 outputs the first error output signal ERR_OUT1 having the second logic value and the second error output signal ERR_OUT2 having the second logic value. When the logic value of the state signal ST1 is a second logic value, the logic value of the state signal ST2 is the second logic value and the logic value of the state signal ST3 is the second logic value, the pre-encoder 321 outputs the first error output signal ERR_OUT1 having the first logic value and the second error output signal ERR_OUT2 having the second logic value.

Therefore, based on Table 2, when a logic value of the first error output signal ERR_OUT1 is a first logic value and a logic value of the second error output signal ERR_OUT2 is the first logic value, the SEV signals SEV[0]<0> to SEV[0]<7> and SEV[1]<0> to SEV[1]<7> indicate the “NE” state. When the logic value of the first error output signal ERR_OUT1 is a second logic value and the logic value of the second error output signal ERR_OUT2 is the first logic value, the plurality of severity signals SEV[0]<0> to SEV[0]<7> and SEV[1]<0> to SEV[1]<7> indicate the “CEs” state. When the logic value of the first error output signal ERR_OUT1 is the second logic value and the logic value of the second error output signal ERR_OUT2 is the second logic value, the plurality of severity signals SEV[0]<0> to SEV[0]<7> and SEV[1]<0> to SEV[1]<7> indicate the “CEm” state. When the logic value of the first error output signal ERR_OUT1 is the first logic value and the logic value of the second error output signal ERR_OUT2 is the second logic value, the plurality of severity signals SEV[0]<0> to SEV[0]<7> and SEV[1]<0> to SEV[1]<7> indicate the “UE” state.

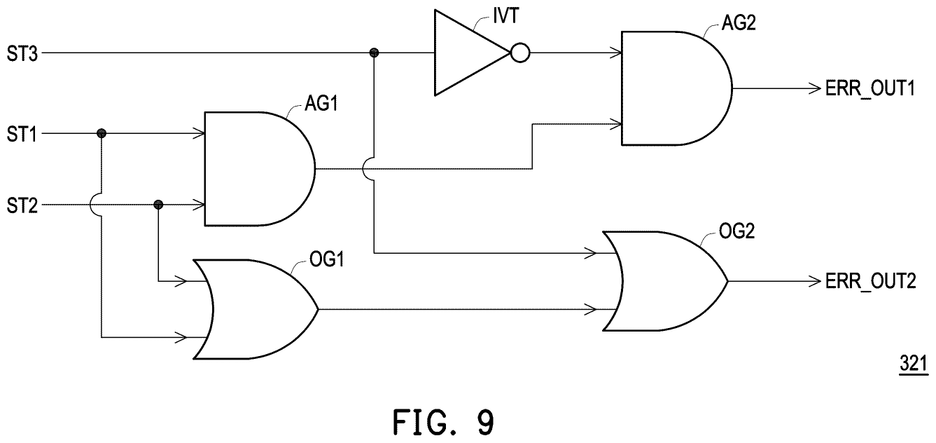

Please refer to FIG. 9, FIG. 9 illustrates a schematic diagram of a pre-encoder according to an embodiment of the disclosure. In the embodiment, the pre-encoder 321 includes AND gates AG1 and AG2, an inverter IVT and OR gates OG1 and OG2. A first input terminal of the AND gate AG1 receives the state signal ST1. A second input terminal of the AND gate AG1 receives the state signal ST2. An input terminal of the inverter IVT receives the state signal ST3. A first input terminal of the AND gate AG2 is coupled to an output terminal of the inverter IVT. A second input terminal of the AND gate AG2 is coupled to an output terminal of the AND gate AG1. An output terminal of the AND gate AG2 outputs the first error output signal ERR_OUT1. A first input terminal of the OR gate OG1 receives the state signal ST1. A second input terminal of the OR gate OG1 receives the second state signal ST2. A first input terminal of the OR gate OG2 receives the state signal ST3. A second input terminal of the OR gate OG2 is coupled to an output terminal of the OR gate OG1. An output terminal of the OR gate OG2 outputs the second error output signal ERR_OUT2. The Table 3 can be realized based on the AND gates AG1 and AG2, the inverter IVT and the OR gates OG1 and OG2.

In the embodiment, based on Table 3 and FIG. 9, when the logic value of the state signal ST3 is the second logic value, the pre-encoder 321 outputs the first error output signal ERR_OUT1 having the first logic value and the second error output signal ERR_OUT2 having the second logic value. Thus, state signal ST3 corresponds to the “UE” state.

In view of the foregoing, the core die provides the at least two state signals based on ECC operation. The core die does not generate the plurality of SEV signals. The logic die generates the plurality of SEV signals according to the at least two state signals. The number of the at least two state signals is less than the number of the plurality of SEV signals. Therefore, a number of via structures of the at least one core die can be decreased. In this way, design complexity of the memory device can be decreased.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A memory device, comprising:
At least one core die, configured to provide at least two state signals based on error check and correction (ECC) operation; and
a logic die, coupled to the least one core die, and configured to generate the at least two state signals to generate a plurality of severity signals, wherein a number of the at least two state signals is lower than a number of the plurality of severity signals.

2. The memory device of claim 1, wherein the logic die comprises:
a pre-encoder, coupled to the least one core die, and configured to generate a first error output signal and a second error output signal according to the at least two state signals; and
a severity signal generator, coupled to the pre-encoder, and configured to generate a plurality of severity signals according to the first error output signal and the second error output signal.

3. The memory device of claim 2, wherein the logic die further comprising:
a serializer, coupled to the severity signal generator, and configured to generate at least one serial severity signal according to the plurality of severity signal.

4. The memory device of claim 3, further comprising:
a controller, coupled to the serializer, and configured to obtain an error type of the least one core die according to the at least one serial severity signal.

5. The memory device of claim 2, wherein:
the at least two state signals comprises a first state signal and a second state signal, and
the pre-encoder comprises:
a decoder, configured to generate a first logic signal, a second logic signal and a third logic signal in response to logic values of the first state signal and the second state signal; and
a logic circuit, coupled to the decoder, and configured to generate the first error output signal and the second error output signal according to the first logic signal, the second logic signal and the third logic signal.

6. The memory device of claim 5, wherein the logic circuit performs first OR logic operation on the first logic signal and the second logic signal to generate the first error output signal, and performs second OR logic operation on the second logic signal and the third logic signal to generate the second error output signal.

7. The memory device of claim 5, wherein the logic circuit comprises:
a first OR gate, a first input terminal of the first OR gate receives the first logic signal, a second input terminal of the first OR gate receives the second logic signal, an output terminal of the first OR gate outputs the first error output signal; and
a second OR gate, a first input terminal of the second OR gate receives the second logic signal, a second input terminal of the second OR gate receives the third logic signal, an output terminal of the second OR gate outputs the second error output signal.

8. The memory device of claim 5, wherein:
the first logic signal corresponds to a correct error single bit state,
the second logic signal corresponds to a correct error multi bit state, and
the third logic signal corresponds to an uncorrectable error bit state.

9. The memory device of claim 8, wherein:
when a logic value of the first error output signal is a first logic value and a logic value of the second error output signal is the first logic value, the plurality of severity signals indicate a no error state,
when the logic value of the first error output signal is a second logic value and the logic value of the second error output signal is the first logic value, the plurality of severity signals indicate the correct error single bit state,
when the logic value of the first error output signal is the second logic value and the logic value of the second error output signal is the second logic value, the plurality of severity signals indicate the correct error multi bit state, and
when the logic value of the first error output signal is the first logic value and the logic value of the second error output signal is the second logic value, the plurality of severity signals indicate the uncorrectable error bit state.

10. The memory device of claim 2, wherein:
the at least two state signals comprises a first state signal, a second state signal and a third state signal, and
the pre-encoder generates the first error output signal and the second error output signal according to the first state signal, the second state signal and the third state signal.

11. The memory device of claim 10, wherein the pre-encoder comprises:
a first AND gate, a first input terminal of the first AND gate receives the first state signal, a second input terminal of the first AND gate receives the second state signal;
an inverter, an input terminal of the inverter receives the third state signal;
a second AND gate, a first input terminal of the second AND gate is coupled to an output terminal of the inverter, a second input terminal of the second AND gate is coupled to an output terminal of the first AND gate, an output terminal of the second AND gate outputs the first error output signal;
a first OR gate, a first input terminal of the first OR gate receives the first state signal, a second input terminal of the first OR gate receives the second state signal;
a second OR gate, a first input terminal of the second OR gate receives the third state signal, a second input terminal of the second OR gate is coupled to an output terminal of the first OR gate, an output terminal of the second OR gate outputs the second error output signal.

12. The memory device of claim 10, wherein the third state signal corresponds to an uncorrectable error bit state.

13. The memory device of claim 10, wherein when a logic value of the first state signal is a first logic value, a logic value of the second state signal is the first logic value and a logic value of the third state signal is the first logic value, the pre-encoder outputs the first error output signal having the first logic value and the second error output signal having the first logic value.

14. The memory device of claim 13, wherein when the logic value of the first state signal is different from the logic value of the second state signal and the logic value of the third state signal is the first logic value, the pre-encoder outputs the first error output signal having a second logic value and the second error output signal having the first logic value.

15. The memory device of claim 13, wherein when the logic value of the first state signal is a second logic value, the logic value of the second state signal is the second logic value and the logic value of the third state signal is the first logic value, the pre-encoder outputs the first error output signal having the second logic value and the second error output signal having the second logic value.

16. The memory device of claim 13, wherein when the logic value of the first state signal is a second logic value, the logic value of the second state signal is the second logic value and the logic value of the third state signal is the second logic value, the pre-encoder outputs the first error output signal having the first logic value and the second error output signal having the second logic value.

17. The memory device of claim 10, wherein:
when a logic value of the first error output signal is a first logic value and a logic value of the second error output signal is the first logic value, the plurality of severity signals indicate a no error state,
when the logic value of the first error output signal is a second logic value and the logic value of the second error output signal is the first logic value, the plurality of severity signals indicate a correct error single bit state,
when the logic value of the first error output signal is the second logic value and the logic value of the second error output signal is the second logic value, the plurality of severity signals indicate a correct error multi bit state, and
when the logic value of the first error output signal is the first logic value and the logic value of the second error output signal is the second logic value, the plurality of severity signals indicate a uncorrectable error bit state.

18. The memory device of claim 2, wherein:
the plurality of severity signals are grouped into a first signal group and a second signal group, and
the severity signal generator provides the first signal group having a first logic value, and provides the second signal group according to the first error output signal and the second error output signal.

19. The memory device of claim 1, wherein the least one core die comprises:
an ECC circuit, configured to perform the ECC operation of the least one core die to generate the at least two state signals.
